(19) United States
(12) Patent Application Publication
(10) Pub. No.: US 2012/0098580 A1
(43) Pub. Date: Apr. 26, 2012

(54) TIMING ADJUSTING CIRCUIT

(76) Inventor: Ping-Ying WANG, Hsinchu City (TW)

(21) Appl. No.: 13/282,187

(22) Filed: Oct. 26, 2011

Related U.S. Application Data
(60) Provisional application No. 61/406,808, filed on Oct. 26, 2010.

(51) Int. Cl. H03L 7/085; G01R 13/02

(52) U.S. Cl. 327/157; 324/76.82

(57) ABSTRACT

A timing adjusting circuit including a time amplifier and a phase adjusting module is provided. The time amplifier is used for increasing the active pulse-width of a phase control signal, so as to generate an adjusted control signal. Based on the adjusted control signal, the phase adjusting module adjusts the phase of an output signal. The phase of the output signal is associated with the active pulse-width of the phase control signal.

### CROSS-REFERENCE TO RELATED APPLICATIONS

This application is based upon and claims the benefit of priority to U.S. Provisional Application No. 61/406,808, filed on Oct. 26, 2010; the entire content of which is incorporated herein by reference for all purpose.

### BACKGROUND

The present invention relates to techniques for adjusting the pulse width of a signal with a time amplifier.

The function of a timing circuit is providing output signals with specific phase and/or frequency. For instance, a timing circuit can generate an output signal and keep the phase of the output signal related with the phase of a reference signal. Phase-locked loops and delay-locked loops widely used in communication systems, multimedia systems, and computer systems are all timing circuits. Signals generated by timing circuits are often taken as reference clocks in other circuits. Hence, the signals must be stable and accurate. Besides signal qualities, the cost of circuits is also an important consideration.

### SUMMARY

To fulfill the aforementioned requirements, new structures for timing adjusting circuits are proposed in the invention. By properly adjusting the pulse-width of a phase control signal, the timing adjusting circuit according to the invention can effectively reduce required chip area and provide good signal quality. Furthermore, the proposed structures can be widely used in many kinds of timing loops including digital phase-locked loops, analog phase-locked loops, and delay-locked loops.

One embodiment according to the invention is a timing adjusting circuit including a time amplifier and a phase adjusting module. The time amplifier is used for increasing the active pulse-width of a phase control signal, so as to generate an adjusted control signal. Based on the adjusted control signal, the phase adjusting module adjusts the phase of an output signal. The phase of the output signal is associated with the active pulse-width of the phase control signal.

Another embodiment according to the invention is a current supply circuit including a time amplifier and a charge/discharge pump. The time amplifier is used for increasing the active pulse-width of a current control signal, so as to generate an adjusted control signal. The charge/discharge pump is used for supplying a charge/discharge current based on the adjusted control signal. The magnitude of the charge/discharge current is associated with the active pulse-width of the current control signal.

Another embodiment according to the invention is a time amplifier including two time amplifying units and a synthesizing module. The first time amplifying unit is used for adjusting the pulse-width of a digital signal, so as to generate a first adjusted signal. The second time amplifying unit connected with the first time amplifying unit in series or in parallel is used for adjusting the pulse-width of the first adjusted signal, so as to generate a second adjusted signal. The synthesizing module is used for adding together the first adjusted signal and the second adjusted signal in time domain or frequency domain.

Another embodiment according to the invention is a phase difference measuring circuit including a phase detector, a time amplifier, a time-to-digital converter, and an estimation module. The phase detector is used for detecting a phase difference between a first signal and a second signal. The time amplifier is used for extending the active pulse-width of the phase difference, so as to generate an adjusted phase difference. The time-to-digital converter is used for converting the adjusted phase difference into a digital signal. The estimation module is used for estimating the phase difference based on the digital signal.

Another embodiment according to the invention is a timing circuit for generating an output signal and keeping the output signal associated with the phase of a reference signal. The timing circuit includes a phase detector and a phase adjusting module. The phase detector is used for detecting a phase difference between the reference signal and a feedback signal. The feedback signal is associated with the output signal. The phase adjusting module is used for adjusting the phase of the output signal based on the phase difference. The phase difference includes a descending signal and an ascending signal. The phase adjusting module includes an additional loading and a reduction loading. As the descending signal is active, the additional loading is turned on; as the ascending signal is active, the reduction loading is turned off. The additional loading and the reduction loading are respectively a MOSFET. The additional loading receives the descending signal at the gate of the MOSFET, and the reduction loading receives the ascending signal at the source of the MOSFET.

The advantage and spirit of the invention may be understood by the following recitations together with the appended drawings.

### BRIEF DESCRIPTION OF THE DRAWINGS

FIG. 1 is the block diagram of the timing adjusting circuit in an embodiment according to the invention.

FIG. 2 is a detailed example of the time amplifier.

FIG. 3(A), FIG. 3(B) and FIG. 4 illustrate detailed embodiments of the phase adjusting module.

FIG. 5 is a schematic diagram of the timing adjusting circuit in another embodiment according to the invention.

FIG. 6 is a schematic diagram of the timing loop in another embodiment according to the invention.

FIG. 7 illustrates the timing adjusting circuit using voltage-controlled delay line in another embodiment according to the invention.

FIG. 8 is the block diagram of the timing adjusting circuit in another embodiment according to the invention.

FIG. 9 shows an example of the timing adjusting circuit further including a time-to-digital converter.

FIG. 10(A)˜FIG. 10(C) illustrate examples of time amplifiers including plural time amplifying units connected in series.

FIG. 11(A) and FIG. 11(B) illustrate examples of time amplifiers including plural time amplifying units connected in parallel.

FIG. 12 is the block diagram of the phase difference measuring circuit in another embodiment according to the invention.

FIG. 13 is the block diagram of the timing loop in another embodiment according to the invention.

FIG. 14 is the block diagram of the current supply circuit in another embodiment according to the invention.

### DETAILED DESCRIPTION

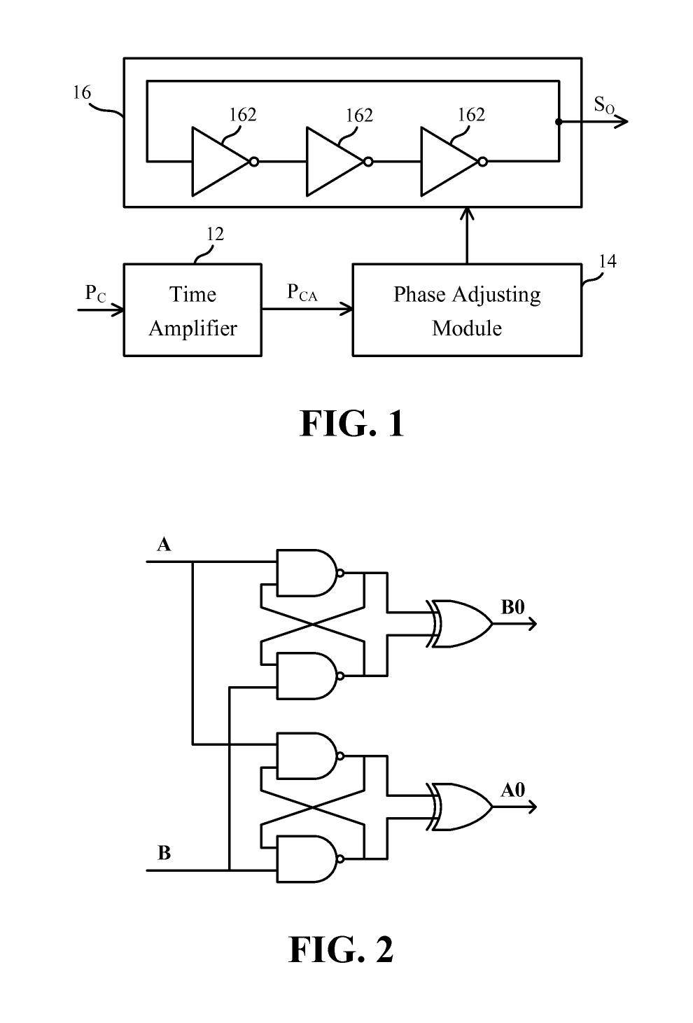

One embodiment according to the invention is the timing adjusting circuit shown in FIG. 1. The timing adjusting circuit includes a time amplifier 12, a phase adjusting module 14 and a ring oscillator 16 formed by inverters 162 connected in series. Active pulse-width of the phase control signal P_{C} is associated with the phase of the output signal S_{O}. The function of the time amplifier 12 is increasing the active pulse-width of the phase control signal P_{C}, so as to generate an adjusted control signal P_{CA}. The function of the phase adjusting module 14 is adjusting the phase of the output signal S_{O} of the ring oscillator 16 based on the adjusted control signal P_{CA}.

FIG. 2 is a detailed example of the time amplifier. Its operating principle is prior art and therefore not described here. For example, through the time amplifier 12 with magnification equal to 10, a high-level pulse originally having pulse-width equal to 100 picoseconds can be changed to have pulse-width equal to 1 nanosecond. Under the condition in which the phase control signal P_{C} includes relative descending signal and ascending signal, the time amplifier 12 can respectively increase the high-level pulse-width of one signal and the low-level pulse-width of the other signal. In practice, magnification of the time amplifier 12 can also be set to be smaller than 1. If the time amplifier 12 provides the phase control signal P_{C} with the magnification smaller than 1 to decrease its high-level pulse-width, it is the same as increasing the low-level pulse-width of the phase control signal P_{C}.

The phase adjusting module 14 in this embodiment is a loading of the ring oscillator 16, and the magnitude of the loading can affect the phase of the output signal S_{O} of the ring oscillator 16. In practice, the loading can be, but not limited to, a capacitive component. The larger the loading provided by the phase adjusting module 14 is, the lower the frequency of the output signal S_{O} generated by the ring oscillator 16 is. The adjusted control signal P_{CA} is used for controlling the magnitude of the loading.

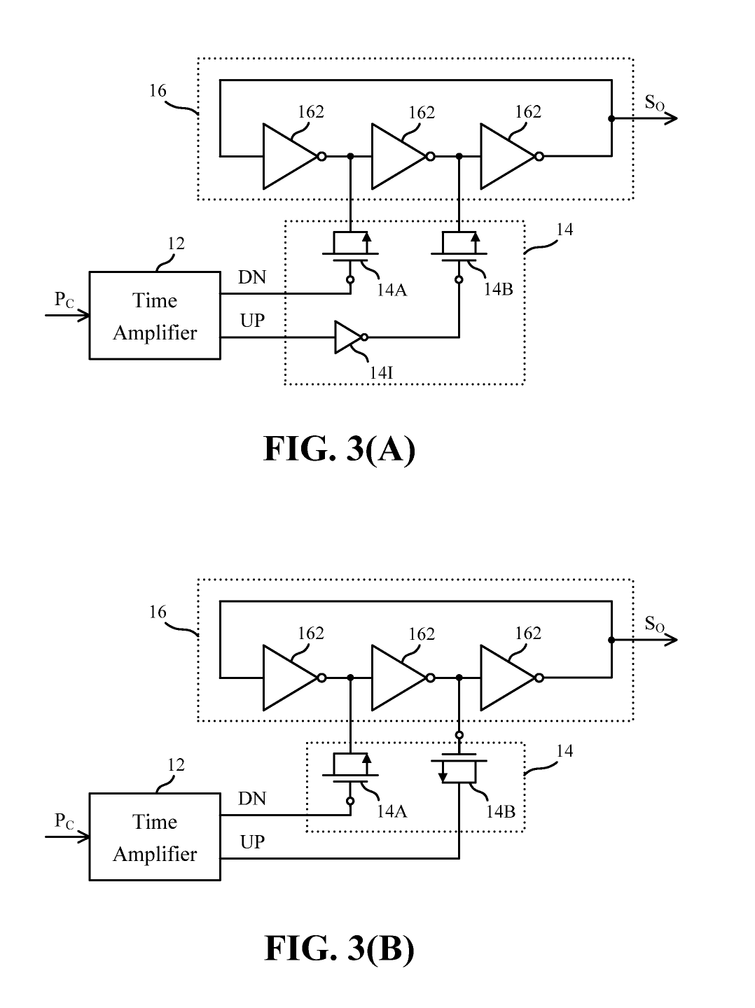

FIG. 3(A) illustrates a detailed embodiment of the phase adjusting module 14. In the embodiment, the adjusted control signal P_{CA} includes a descending signal DN and an ascending signal UP, and the phase adjusting module 14 includes an additional loading 14A and a reduction loading 14B. It is noted though the loading is an N-type MOSFET capacitor in this embodiment, but in practice, it can be implemented with other components. Besides, even it is not shown in the figure, the phase control signal P_{C} itself can also includes relative descending signal and ascending signal. In this embodiment, the additional loading 14A is default to be turned off, not being part of the loading of the ring oscillator 16, while the reduction loading 14B is default to be turned on to be part of the default loading of the ring oscillator 16. As the descending signal DN is active, the additional loading 14A is turned on to make the frequency of the output signal S_{O} lower. On the contrary, as the ascending signal UP is active, the reduction loading 14B is turned off to make the frequency of the output signal S_{O} higher.

The circuit extends the time duration which the descending signal DN or the ascending signal UP is active by adjusting the pulse-width of the phase control signal P_{C}. Regarding the circuit illustrated in FIG. 3A, the function of the time amplifier 12 is to extend the time duration which the additional loading 14A is turned on or the reduction loading 14B is turned off. Taking the additional loading 14A for example, under the condition in which the magnitude of the additional loading 14A is fixed, the longer the descending signal DN is active, the more the phase/frequency of the output signal SO is effected, and it is equal to using larger additional loading 14A. Assuming the magnification provide by the time amplifier 12 is ten, the magnitude of the additional loading 14A can be reduced to be one tenth compared with condition in which the time amplifier 12 is not included. Reducing the additional loading 14A and the reduction loading 14B can not only save the area of the chip but also effectively reduce the short-term impulses appearing in the output signal S_{O} as the loading is turned on/off. Furthermore, the reducing the additional loading 14A and the reduction loading 14B also increases the bandwidth of the ring oscillator 16.

As shown in FIG. 3(B), in another embodiment, the reduction loading 14B is still a MOSFET, but its gate is connected to the inverter 162 and its source/drain is used for receiving the ascending signal UP. Benefit of the design is that the inverter 141 originally disposed between the time amplifier 12 and the reduction loading 14B can be removed. As shown in FIG. 4, in another embodiment, the additional loading 14A and the reduction loading 14B can also be designed to be distributed at the output ends of the inverters 162.

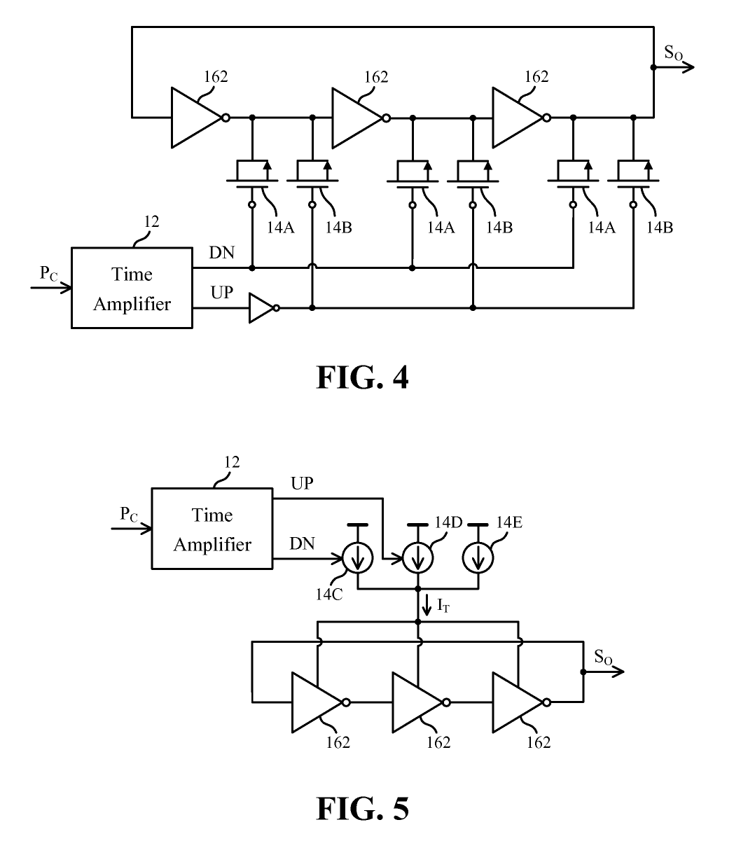

FIG. 5 is a schematic diagram of the timing adjusting circuit in another embodiment according to the invention. In this embodiment, the phase adjusting module 14 includes supply current sources 14C˜14E, the total current I_{T} provide by the three current sources is the operating current of the inverters 162. The larger the current I_{T} is, the higher the frequency of the output signal S_{O} generated by the ring oscillator 16 is. The descending signal DN and the ascending signal UP provided by the time amplifier 12 are used for controlling the magnitude of the current I_{T}. In practice, the current source 14C and 14D can be, but not limited to, implemented with MOSFETs with gates controlled by the DN/UP signals.

In this embodiment, the current source 14C is default to be turned on while the current source 14D is default to be turned off. As the descending signal DN is active, the current source 14C is turned off to make the frequency of the output signal S_{O} lower. On the contrary, as the ascending signal UP is active, the current source 14D is turned off to make the frequency of the output signal S_{O} higher. The larger the current provided by the current sources 14C and 14D is, the more the phase/frequency of the output signal affected upon turning on/off the two current sources is. Therefore, if a circuit designer wants to increase the adjustable range, larger current resources 14C and 14D are required.

The function of the time amplifier 12 is to extend the time duration which the current source 14C is turned off or the current source 14D is turned on. Take the current source 14C for example, under the condition in which the magnitude of the additional current source 14C is fixed, the longer the descending signal DN is active, the more the phase/frequency of the output signal SO is affected. Regarding the total phase change of the output signal S_{O}, including time amplifier 12 equals to using larger additional current source 14C. Assuming that the magnification provide by the time amplifier 12 is ten, the magnitude of the current source 14C can be reduced to be one tenth compared with condition in which the time amplifier 12 is not included. Reducing the current source 14C and 14D can effectively save the chip area.

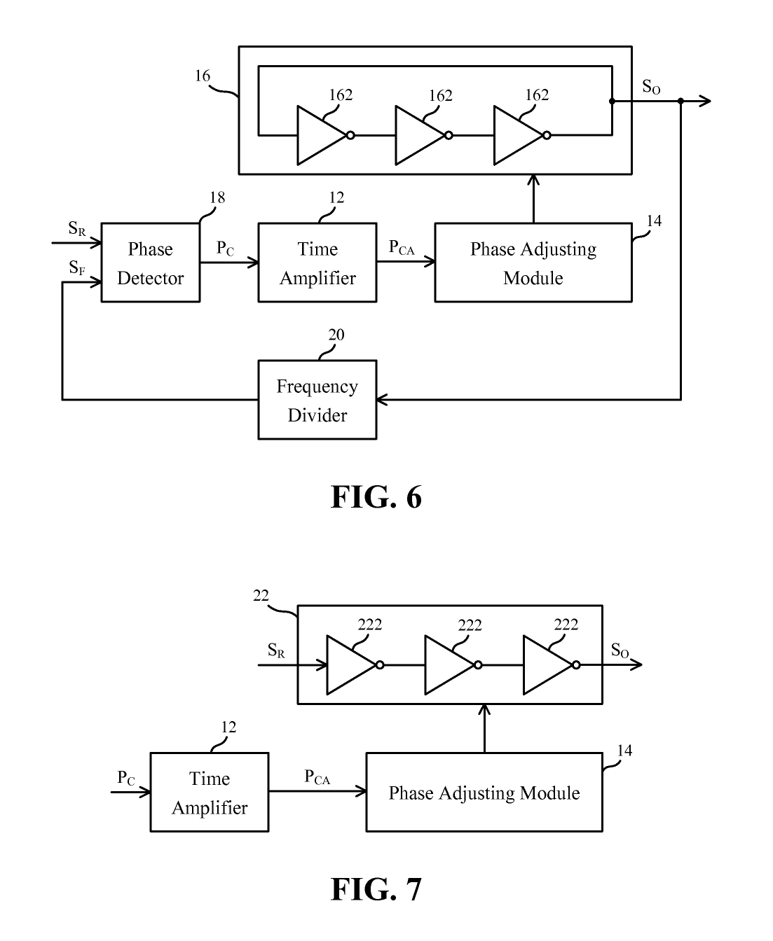

Another embodiment according to the invention is the timing adjusting circuit as shown in FIG. 6. Compared with the structure illustrated in FIG. 1, the timing adjusting circuit further includes a phase detector 18 and a frequency divider 20. The phase detector 18 is used for detecting a phase difference between a reference signal S_{R} and a feedback signal S_{F}; the phase difference is the phase control signal. The frequency divider 20 provides a dividing ratio to maintain a specific corresponding relation between the feedback signal S_{F} and the output signal S_{O}. The phase of the output signal S_{O} generated by the loop is kept associated with the phase of the reference signal S_{R}. The phase adjusting modules 14 introduced in FIG. 3(A), FIG. 3(B), FIG. 4 and FIG. 5 can all be applied in this structure to achieve the result of reducing the loading or magnitude of the current source.

It is noted the ring oscillators in FIG. 1, FIG. 3(A), FIG. 3(B), FIG. 4, FIG. 5, and FIG. 5 can be replaced by other kinds of oscillator such as LC oscillators.

Another embodiment according to the invention is the timing adjusting circuit illustrated in FIG. 7. The timing adjusting circuit includes a time amplifier 12, a phase adjusting module 14, and a voltage-controlled delay line 22 formed by inverters 222 connected in series. For the voltage-controlled delay line 22, changing its loading or operating current can change the phase of its output signal S_{O}. Therefore, the phase adjusting modules 14 introduced in FIG. 3(A), FIG. 3(B), FIG. 4 and FIG. 5, and the feedback structure mentioned in FIG. 6 can all be applied in the timing adjusting circuit show in FIG. 7 to achieve the result of reducing the loading or magnitude of the current source.

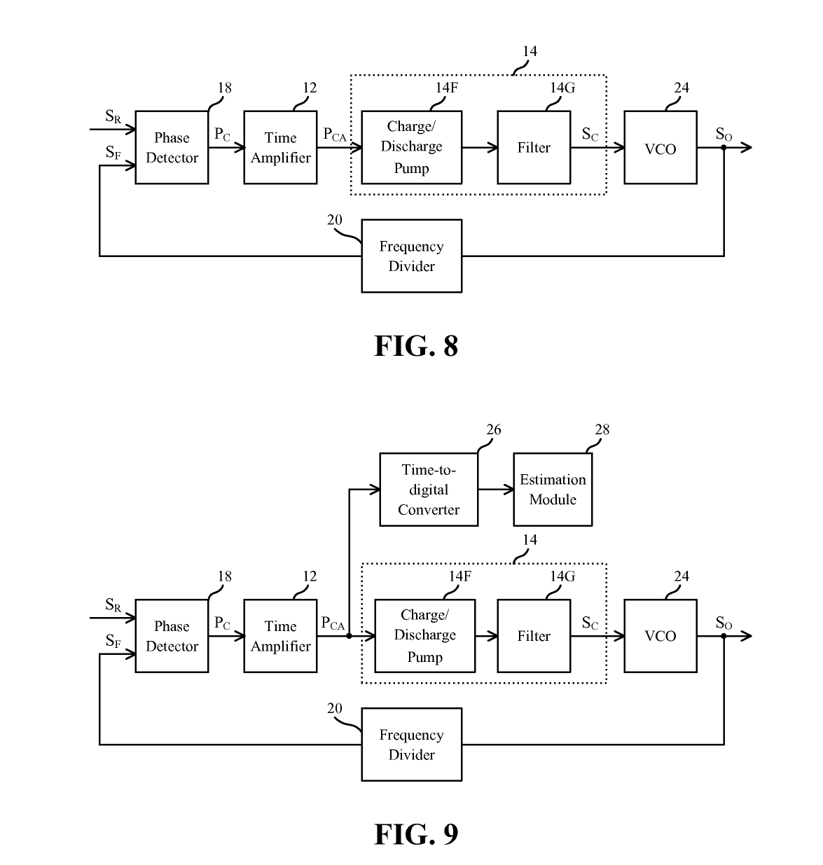

Another embodiment according to the invention is the timing adjusting circuit as illustrated in FIG. 8. The timing adjusting circuit includes a time amplifier 12, a phase adjusting module 14, a phase detector 18 and an oscillator 24. The phase adjusting module 14 in this embodiment includes a charge/discharge pump 14F and a filter 14G. The charge/discharge pump 14F supplies a charge/discharge current based on the adjusted control signal. The filter 14G is used for receiving the charge/discharge current and supplying a filtered control signal S_{C}. The oscillator 24 generates the output signal S_{O} based on the filtered control signal S_{C}.

For example, assuming the frequency of the control signal S_{C} is substantially proportional to the frequency of the output signal S_{O}, the charge/discharge pump 14F can charge the filter 14G as the ascending signal of the adjusted control signal P_{CA} is active, so as to increase the control signal S_{C} and thereby increase the frequency the output signal S_{O}. The longer the active pulse-width of the ascending signal UP or the descending signal DN of the adjusted control signal P_{CA} is, the more the frequency of the output signal S_{O} affected is. Under the condition in which the current of the charge/discharge pump 14F is fixed, the longer the signal DN/UP is active, the more the phase/frequency of the output signal S_{O} is affected. Therefore, the existence of the time amplifier 12 can reduce the charge/discharge pump 14F to save the chip area. Besides, the magnification of the pulse-width provided by the time amplifier 12 can effectively reduce the equivalent noise fed back to the input of the time amplifier 12, and therefore the noise-related requirement for the charge/discharge pump 14F can be lower.

As shown in FIG. 9, in another embodiment, the timing adjusting circuit in FIG. 8 can further include a time-to-digital converter 26 and an estimation module 28. The time-to-digital converter 26 is coupled to the output of the time amplifier 12 and used for converting the adjusted control signal into a digital signal. The estimation module 28 is used for estimating a jitter amount of the timing adjusting circuit based on the digital signal. Compared with the phase control signal P_{C}, the adjusted control signal P_{CA} with larger active pulse-width is more convenient for following measurement.

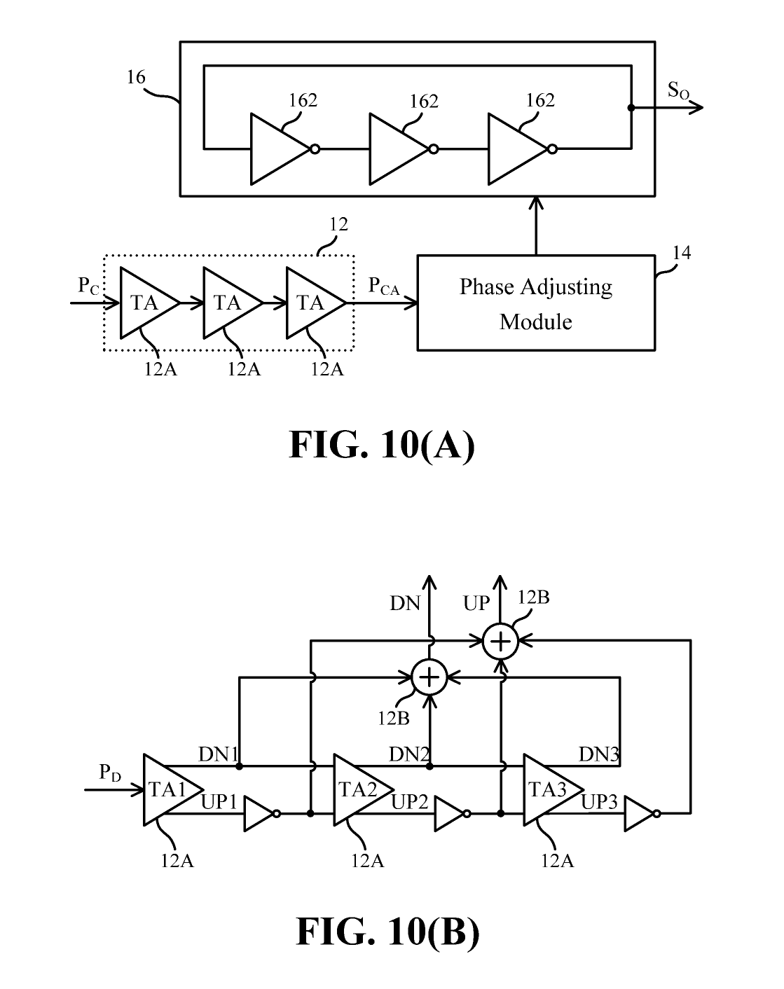

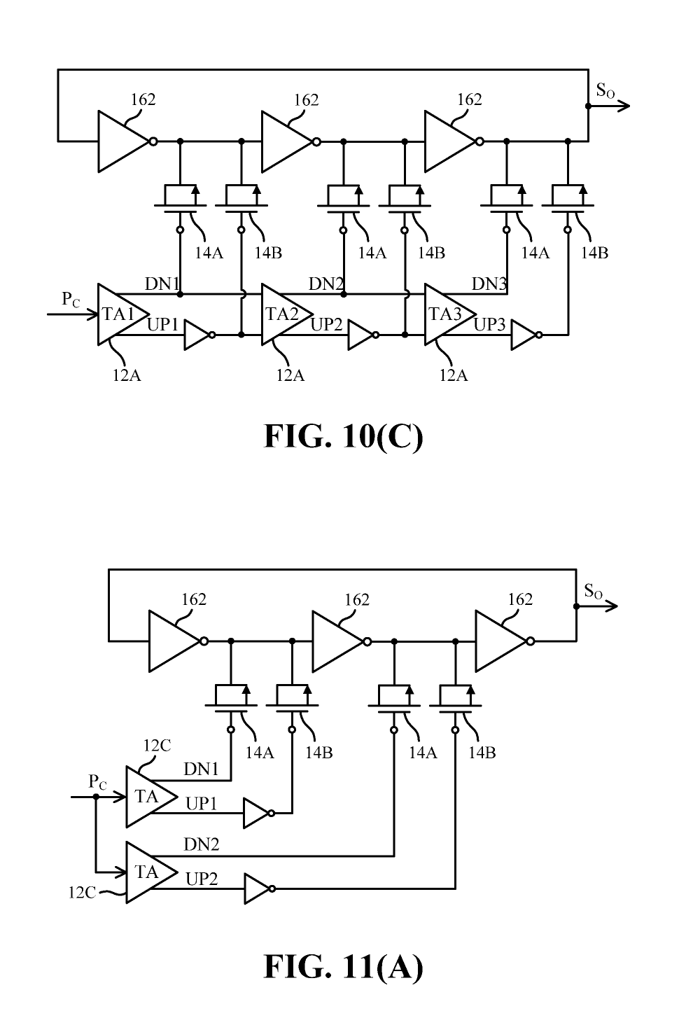

As shown in FIG. 10(A), in another embodiment, the time amplifier 12 can include a plurality of time amplifying units 12A connected in series. For example, the time amplifier 12 can be a time amplifying unit with magnification equal to 8. It can also be composed of three time amplifying units 12A with magnification equal to 2 connected in series. It is noted the magnification of the respective time amplifying unit 12A is not limited to an integer or a number larger than 1.

As shown in FIG. 10(B), in another embodiment, the time amplifier 12 can further include two adders 12B for adding together the adjusted control signals respectively generated by the time amplifying units 12A. The first adder 12B is used for adding together DN1˜DN3, and the second adder 12B is used for adding together UP1˜UP3. Taking the condition in FIG. 10(A) for example, the added results are provided to the ring oscillator 16 for adjusting the phase of the output signal S_{O}. As shown in FIG. 10(C), in another embodiment, the adjusted control signals generated by the time amplifying units 12A can also be used for controlling different loadings.

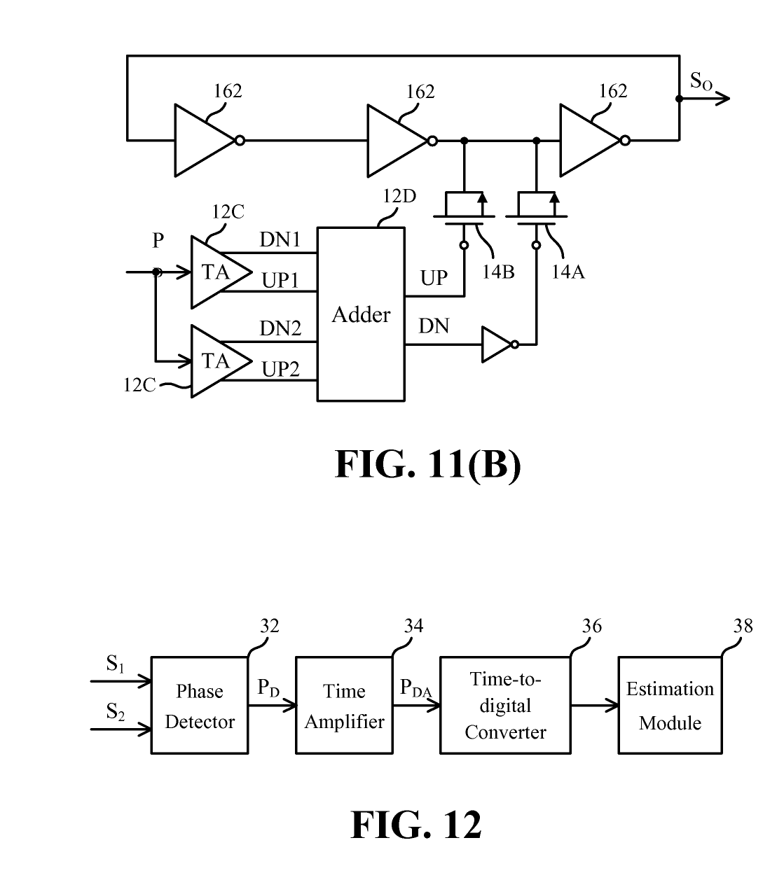

As shown in FIG. 11(A), in another embodiment, the time amplifier 12 includes a plurality of time amplifying units 12C connected in parallel. The time amplifying units 12C can be used for receiving the phase control signal P_{C} and adjusting the active pulse-width of the phase control signal P_{C} by turns. For example, assuming the cycle time of a reference clock is T, during the first cycle, the first time amplifying unit 12C is used for amplifying the phase control signal P_{C} to generate the ascending signal UP1 and the descending signal DN1. During the following second cycle, the second time amplifying unit 12C is used for amplifying the phase control signal P_{C} to generate the ascending signal UP2 and the descending signal DN2, and so on. In this embodiment, the adjusted control signals generated by the two time amplifying units 12C are used for controlling loadings of different inverters 162.

As shown in FIG. 11(B), in another embodiment, the time amplifier 12 includes an adder 12D for adding together the adjusted control signals respectively generated by the time amplifying units in time domain. The signals UP1 and UP2 are added together to generate the ascending signal UP. The signals DN1 and DN2 are added together to generate the descending signal DN. For example, assuming the active pulse-width of the ascending signal UP1 generated by the first time amplifying unit 12C is one nanosecond, and the active pulse-width of the ascending signal UP2 generated by the second time amplifying unit 12C is three nanoseconds, then the pulse-width of the ascending signal UP outputted by the adder 12D is four nanoseconds.

To sum up, the time amplifier 12 can be designed to include plural time amplifying units connected in parallel or in series, and the timing adjusting circuit according to the invention can include a synthesizing module for adding together the adjusted control signals respectively generated by the time amplifying units. Regarding the conditions in FIG. 10(B) and FIG. 11(B), the synthesizing module is an adder. As to the situation in FIG. 10(C) and FIG. 11(A), the adjusted signals generated by the time amplifying units respectively affects the phase/frequency of the output signal S_{O}; the effect is equivalent to adding together the adjusted signals generated by the time amplifying units in frequency domain in the ring oscillator 16. In other words, the synthesizing module can also be an oscillator or a voltage-controlled delay line as shown in FIG. 7.

It is noted the circuit structures in FIG. 10(A)˜FIG. 10(C), FIG. 11(A) and FIG. 11(B) can all achieve the aforementioned result of extending pulse-widths. In practice, the timing loops in FIG. 1 and FIG. 3˜FIG. 11(B) can further include other circuit blocks not depicted. For example, the phase detector 18 and the time amplifier 12 can be set in a proportional path of a phase-locked loop, and the phase-locked loop further include an integral path; the two paths generate together the control signal for controlling the following oscillator.

Above mentioned embodiments commonly include a time amplifier and a phase adjusting module. The time amplifier is used for increasing the active pulse-width of a phase control signal, so as to generate an adjusted control signal. The phase adjusting module is used for adjusting the phase of an output signal based on the adjusted control signal. The phase of the output signal is associated with the active pulse-width of the phase control signal

Another embodiment according to the invention is a time amplifier including a plurality of time amplifying units connected in series and a synthesizing module. The synthesizing module is used for adding together the adjusted signals respectively generated by the time amplifying units in time domain or frequency domain. Regarding the condition in FIG. 10(B), the adder 12B is the synthesizing module which adds together the adjusted signals respectively generated by the time amplifying units in time domain. Regarding the condition in FIG. 10(C), the adjusted signals generated by the time amplifying units respectively affects the phase/frequency of the output signal S_{O}; the effect is equivalent to adding together the adjusted signals generated by the time amplifying units in frequency domain in the ring oscillator 16. The phase adjusting module 16 can be viewed as the synthesizing module.

Another embodiment according to the invention is a time amplifier including a plurality of time amplifying units connected in parallel and a synthesizing module. The synthesizing module is used for adding together the adjusted signals respectively generated by the time amplifying units in time domain or frequency domain. Regarding the condition in FIG. 11(A), the ring oscillator 16 is the synthesizing module. The adjusted signals generated by the time amplifying units 12C respectively affects the phase/frequency of the output signal S_{O}; the effect is equivalent to adding together the adjusted signals generated by the time amplifying units in frequency domain in the ring oscillator 16. Regarding the condition in FIG. 11(B), the adder 12D is the synthesizing module which adds together the adjusted signals generated by the time amplifying units 12C in time domain.

Another embodiment according to the invention is a phase difference measuring circuit, as shown in FIG. 12. The phase difference measuring circuit includes a phase detector 32, a time amplifier 34, a time-to-digital converter 36, and an estimation module 38. The phase detector 32 is used for detecting a phase difference Pₚ between a first signal S₁ and a second signal S₂. The time amplifier 34 is coupled to the phase detector 32 and used for extending the active pulse-width of the phase difference P_{D}, so as to generate an adjusted phase difference P_{DA}. The time-to-digital converter 36 is coupled to the time amplifier 34 and used for converting the adjusted phase difference P_{DA} into a digital signal. The estimation module 38 estimates the phase difference P_{D} based on the digital signal. As mentioned above, compared with the phase difference P_{D}, the adjusted phase difference P_{DA} with larger active pulse-width is more convenient for following measurement.

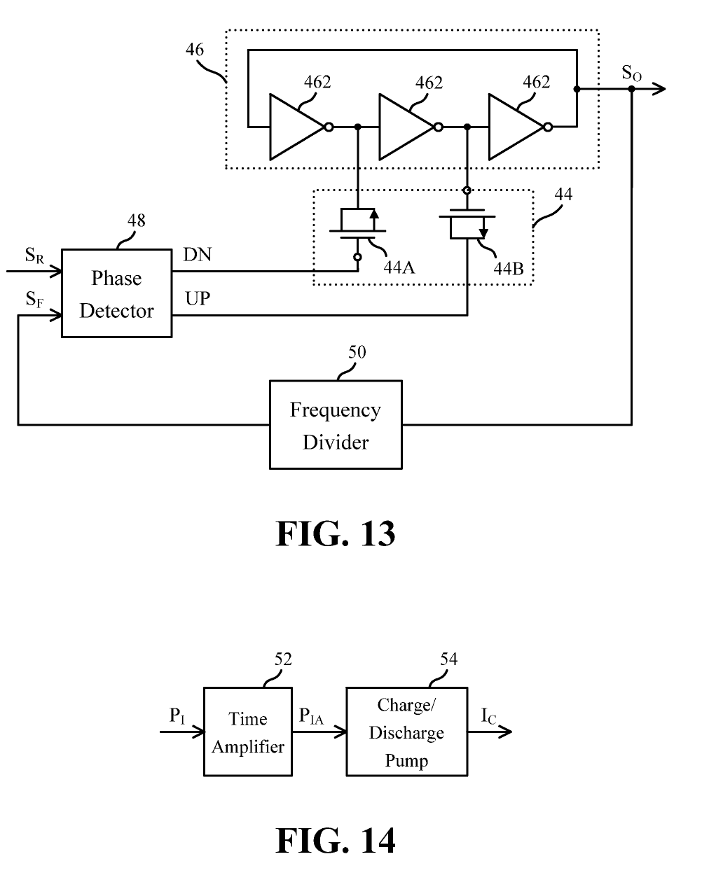

Another embodiment according to the invention is a timing loop, as shown in FIG. 13, for generating an output signal S_{O} and keeping the output signal S_{O} associated with the phase of a reference signal S_{R}. The timing loop includes a phase detector 48, a phase adjusting module 44, a ring oscillator 46, and a frequency divider 50. The phase detector 48 is used for detecting a phase difference between the reference signal S_{R} and a feedback signal S_{F}, so as to generate phase difference signals UP/DN. The frequency divider 50 provides a specific frequency relation between the feedback signal S_{F} and the output signal S_{O}. The ring oscillator 46 is used for generating the output signal S_{O}. The phase adjusting module 44 is used for adjusting the phase of the output signal S_{O} based on the phase difference signals UP/DN. It is noted in practice the oscillator in the figure is not limited to a ring oscillator. For example, the block 46 can also be replaced by the voltage-controlled delay line in FIG. 7.

As shown in FIG. 13, the phase adjusting module 44 includes an additional loading 44A and a reduction loading 44B. As the descending signal DN is active, the additional loading 44A is turned on; as the ascending signal UP is active, the reduction loading 44B is turned off. In this embodiment, the additional loading 44A and the reduction loading 44B are respectively an N-type MOSFET capacitor. As shown in FIG. 13, the additional loading 44A receives the descending signal DN with the gate of the MOSFET capacitor, and the reduction loading 44B receives the ascending signal UP with the source of the MOSFET capacitor.

Another embodiment according to the invention is a current supply circuit shown in FIG. 14. The current supply circuit includes a time amplifier 52 and a charge/discharge pump 54. The time amplifier 52 is used for increasing the active pulse-width of a current control signal P_{I}, so as to generate an adjusted control signal P_{IA}. The charge/discharge pump 54 is used for supplying a charge/discharge current I_{C} based on the adjusted control signal P_{IA}. The magnitude of the charge/discharge current is associated with the active pulse-width of the current control signal P_{IA}. As mentioned above, the existence of the time amplifier 54 can reduce size of the charge/discharge pump 54, so as to save chip area. Besides, the magnification of the pulse-width provided by the time amplifier 12 can effectively reduce the equivalent noise fed back to the input of the time amplifier 12, and therefore the noise-related requirement for the charge/discharge pump 54 can be lower.

In practice, the time amplifier 52 can also be designed to include plural time amplifying units connected in parallel or in series, and the charge/discharge pump 54 can include a synthesizing module for adding together the adjusted control signals respectively generated by the time amplifying units. As the time amplifying units are connected in parallel, the plural time amplifying units receive the phase control signals and adjust the active pulse-widths of the phase control signals by turns. For detailed operations, please refer to the above embodiments.

As mentioned above, by properly adjusting the pulse-width of the phase control signal, the timing circuit according to the invention can effectively reduce the chip area and provide good signal quality. Furthermore, the circuit structures can be widely used in many timing loops including various digital phase-locked loops, analog phase-locked loops and delay-locked loops.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A timing adjusting circuit, comprising:
a time amplifier for increasing the active pulse-width of a phase control signal, so as to generate an adjusted control signal; and
a phase adjusting module for adjusting the phase of an output signal based on the adjusted control signal, wherein the phase of the output signal is associated with the active pulse-width of the phase control signal.

2. The timing adjusting circuit of claim 1, further comprising:
an oscillator or a voltage-controlled delay line for generating the output signal;
wherein the phase adjusting module is a loading of the oscillator or the voltagecontrolled delay line, the magnitude of the loading is associated with the phase of the output signal, and the adjusted control signal is used for controlling the magnitude of the loading.

3. The timing adjusting circuit of claim 2, wherein the adjusted control signal comprises a descending signal and an ascending signal, the phase adjusting module comprises an additional loading and a reduction loading; as the descending signal is active, the additional loading is turned on; as the ascending signal is active, the reduction loading is turned off.

4. The timing adjusting circuit of claim 1, further comprising:
an oscillator or a voltage-controlled delay line for generating the output signal;
wherein the phase adjusting module is a supply current source of the oscillator or the voltage-controlled delay line, the magnitude of the current supplied by the supply current source is associated with the phase of the output signal, and the adjusted control signal is used for controlling the magnitude of the current.

5. The timing adjusting circuit of claim 1, further comprising:
a phase detector for detecting a phase difference between a reference signal and a feedback signal, the phase difference being the phase control signal, wherein the feedback signal is associated with the output signal.

6. The timing adjusting circuit of claim 5, wherein the phase adjusting module further comprising:
a charge/discharge pump for supplying a charge/discharge current based on the adjusted control signal; and
a filter for receiving the charge/discharge current and supplying a filtered control signal;
the timing adjusting circuit further comprising:
an oscillator for generating the output signal based on the filtered control signal.

7. The timing adjusting circuit of claim 6, further comprising:
a time-to-digital converter for converting the adjusted control signal into a digital signal; and
an estimation module for estimating a jitter amount of the timing adjusting circuit based on the digital signal.

8. The timing adjusting circuit of claim 1, wherein the time amplifier comprises a plurality of time amplifying units connected in parallel or in series; the timing adjusting circuit further comprising:
a synthesizing module for adding together the adjusted control signals respectively generated by the time amplifying units in time domain or frequency domain;
wherein as the time amplifying units are connected in parallel, the time amplifying units receive the phase control signal and adjust the active pulse-width of the phase control signal by turns.

9. The timing adjusting circuit of claim 8, wherein the synthesizing module is an oscillator, a voltage-controlled delay line, or an adder.

10. A current supply circuit, comprising:
a time amplifier for increasing the active pulse-width of a current control signal, so as to generate an adjusted control signal; and
a charge/discharge pump for supplying a charge/discharge current based on the adjusted control signal, wherein the magnitude of the charge/discharge current is associated with the active pulse-width of the current control signal.

11. The current supply circuit of claim 10, wherein the time amplifier comprises a plurality of time amplifying units connected in parallel or in series, and the charge/discharge pump comprises:
a synthesizing module for adding together the adjusted control signals respectively generated by the time amplifying units in time domain or frequency domain;
wherein as the time amplifying units are connected in parallel, the time amplifying units receive the current control signal and adjust the active pulse-width of the current control signal by turns.

12. A time amplifier, comprising:
a first time amplifying unit for adjusting the pulse-width of a digital signal, so as to generate a first adjusted signal;
a second time amplifying unit, when the second time amplifying unit is connected with the first time amplifying unit in series, the second time amplifying unit adjusting the pulse-width of the first adjusted signal, so as to generate a second adjusted signal; when the second time amplifying unit is connected with the first time amplifying unit in parallel, the second time amplifying unit adjusting the pulse-width of the digital signal, so as to generate the second adjusted signal; and
a synthesizing module for adding together the first adjusted signal and the second adjusted signal in time domain or frequency domain.

13. A phase difference measuring circuit, comprising:
a phase detector for detecting a phase difference between a first signal and a second signal;
a time amplifier for extending the active pulse-width of the phase difference, so as to generate an adjusted phase difference;
a time-to-digital converter for converting the adjusted phase difference into a digital signal; and
an estimation module for estimating the phase difference based on the digital signal.

14. A timing loop for generating an output signal and keeping the output signal associated with the phase of a reference signal, the timing loop comprising:
a phase detector for detecting a phase difference between the reference signal and a feedback signal, wherein the feedback signal is associated with the output signal; and
a phase adjusting module for adjusting the phase of the output signal based on the phase difference;
wherein the phase difference comprises a descending signal and an ascending signal, the phase adjusting module comprises an additional loading and a reduction loading; as the descending signal is active, the additional loading is turned on; as the ascending signal is active, the reduction loading is turned off; the additional loading and the reduction loading are respectively a MOSFET, the additional loading receives the descending signal with the gate of the MOSFET, and the reduction loading receives the ascending signal with the source of the MOSFET.

15. The timing loop of claim 14, wherein the phase adjusting module comprises a ring oscillator or a voltage-controlled delay line.
